(19) United States
(12) Patent Application Publication
(10) Pub. No.: US 2019/0108810 A1
(43) Pub. Date: Apr. 11, 2019

(54) SHIFT REGISTER AND DISPLAY DEVICE PROVIDED WITH SAME

(71) Applicant: SHARP KABUSHIKI KAISHA, Osaka (JP)

(72) Inventors: YASUAKI IWASE, Sakai City (JP); TAKUYA WATANABE, Sakai City (JP); AKIRA TAGAWA, Sakai City (JP); TAKATSUGU KUSUMI, Sakai City (JP); YOHEI TAKEUCHI, Sakai City (JP)

(21) Appl. No.: 16/155,631

(22) Filed: Oct. 9, 2018

(30) Foreign Application Priority Data
Oct. 10, 2017 (JP) 2017-196588

(51) Int. Cl. G09G 3/36; G06F 3/041; G11C 19/28

(52) U.S. Cl. CPC G09G 3/3677; G06F 3/0412; G09G 2300/0426; G09G 2310/0286; G09G 2310/08; G11C 19/28

(57) ABSTRACT

A unit circuit 4 that forms each stage of a shift register is configured by a transfer unit 401 having substantially the same configuration as that of the conventional unit circuit, a state memory unit 402 configured to store a state of a first node N1 within the transfer unit 401 when suspension of scanning is performed, and a connecting unit 403 that connects the state memory unit 402 with the transfer unit 401 so that an electric charge based on an output signal QX from the state memory unit 402 is supplied to the first node N1. A clock operation of control clock signals CKX and CKXB for controlling an operation of the state memory unit 402 is performed when a clock operation of a gate clock signal is suspended.

### BACKGROUND OF THE INVENTION

### 1. Field of the Invention

The present disclosure relates to a shift register, and in particular to a shift register provided for a display device having a touch panel.

### 2. Description of Related Art

Conventionally, there is known an active matrix-type liquid crystal display device including a display unit that includes a plurality of source bus lines (video signal lines) and a plurality of gate bus lines (scanning signal lines). For such a liquid crystal display device, conventionally, a gate driver (scanning signal line drive circuit) for driving the gate bus lines is often mounted as an IC (Integrated Circuit) chip on the periphery of a substrate that constitutes a liquid crystal panel. However, in recent years, it becomes increasingly common to provide a gate driver directly on a TFT substrate which is one of two glass substrates that constitute a liquid crystal panel. Such a gate driver is called a “monolithic gate driver”, and the like.

In a display unit of an active matrix-type liquid crystal display device, a plurality of source bus lines, a plurality of gate bus lines, and a plurality of pixel formation portions disposed at respective intersections of the plurality of source bus lines and the plurality of gate bus lines are formed. The plurality of pixel formation portions are arranged in a matrix and form a pixel array. Each of the pixel formation portions includes: a thin film transistor which is a switching element having a gate terminal connected to a gate bus line that passes through a corresponding intersection and a source terminal connected to a source bus line that passes through the intersection; a pixel capacitance for holding a pixel voltage value; and the like. The active matrix-type liquid crystal display device is also provided with the gate driver described above and a source driver (video signal line drive circuit) for driving the source bus lines.

Video signals representing pixel voltage values are transmitted by the source bus lines. However, each of the source bus lines cannot transmit a video signal representing pixel voltage values for a plurality of rows at one time (simultaneously). Accordingly, writing (charging) of the video signals to the pixel capacitances in the pixel formation portions arranged in a matrix is performed sequentially row by row. Therefore, the gate driver is configured by a shift register including a plurality of stages so that the plurality of gate bus lines are sequentially selected for a predetermined period. Further, by sequentially outputting active scanning signals from the respective stages of the shift register, writing of the video signals to the pixel capacitances is performed sequentially row by row as described above.

As used herein, a circuit that forms each of the stages of the shift register is referred to as a “unit circuit”. Further, sequentially selecting the gate bus lines one by one from a first row to a last row is simply referred to as “scanning”, and stopping the scanning in the course of scanning from the first row to the last row is referred to as “suspension of scanning”. Moreover, a period during which the scanning is suspended is referred to as a “suspension period”.

FIG. 29 is a circuit diagram illustrating an example of a configuration of a conventional unit circuit. In the unit circuit illustrated in FIG. 29, when a set signal S changes from low level to high level, a potential of the first node N1 increases due to pre-charging. By an input clock signal CLKin changing from low level to high level when the first node N1 is in a pre-charged state in this manner, the potential of the first node N1 increases to a large extent, and an output signal Q is turned to high level. With this, a gate bus line connected to this unit circuit is turned to a selected state. By sequentially performing the above operation from a first stage to a last stage of the shift register, the plurality of gate bus lines provided for the display unit are sequentially turned to the selected state for a predetermined period.

Meanwhile, in recent years, a liquid crystal display device having a configuration in which a touch panel and a liquid crystal panel are combined in one piece has been widely spread. With such a liquid crystal display device, it is necessary to perform processing for the touch panel (e.g., processing for detecting a touch position) when scanning is not performed. In this regard, the conventional liquid crystal display device cannot stop scanning after a gate bus line of the first row is selected until a gate bus line of the last row is selected. This is because of the following reason. When the scanning is to be restarted from a scanning stop position after the suspension of scanning, it is necessary for a unit circuit corresponding to the scanning stop position (restart position) to maintain a state in which the first node N1 (see FIG. 29) is pre-charged throughout the suspension period. However, if threshold voltages at thin film transistors T12, T13, and T16 are low, charge leakage may occur at the thin film transistors T12, T13, and T16 during the suspension period. If charge leakage occurs, the potential of the first node N1 decreases during the suspension period as illustrated in FIG. 30 for example. In such a case, the potential of the output signal Q may not sufficiently increase, even when the input clock signal CLKin changes from low level to high level after the suspension period is over. This results in an abnormal operation. As described above, it is not possible for the conventional liquid crystal display device to perform suspension of scanning without causing an abnormal operation.

Therefore, Japanese Laid-Open Patent Publication No. 2014-182203 discloses the invention relating to a shift register capable of enabling suspension of scanning by making a configuration of a unit circuit (“transfer circuit” in Japanese Laid-Open Patent Publication No. 2014-182203) corresponding to a position at which suspension of scanning is to be performed to be able to hold a potential of an inputted shift signal (shift pulse) for a long period.

However, according to the shift register disclosed in Japanese Laid-Open Patent Publication No. 2014-182203, suspension of scanning may be performed only at a specific position, and it is not possible to perform suspension of scanning at any position. As described above, the shift register disclosed in Japanese Laid-Open Patent Publication No. 2014-182203 lacks versatility. Accordingly, for example, it is not possible for the liquid crystal display device having a configuration in which a touch panel and a liquid crystal panel are combined in one piece to quickly perform processing for detecting a touch position. In particular, in recent years, development of a full in-cell type touch panel utilizing a common electrode as an electrode for touch position detection is conducted actively, and performing suspension of scanning at any position is becoming essential.

### SUMMARY OF THE INVENTION

Thus, it is desired to realize a shift register capable of performing suspension of scanning at any stage without causing an abnormal operation.

A shift register according to some embodiments is a shift register performing a shift operation based on a shift clock signal group including a plurality of clock signals, the shift register being configured by a plurality of stages, wherein

a unit circuit that forms each of the stages includes:
a transfer unit having a first charge holding node for holding an electric charge in order to output an output signal at on level, the transfer unit being configured to output an output signal at on level based on one of the plurality of clock signals included in the shift clock signal group when a level of the first charge holding node is on level;
a state memory unit having a second charge holding node for holding an electric charge in order to output a charge supply signal at on level, the state memory unit being configured to output a charge supply signal at on level based on a first control clock signal when a level of the second charge holding node is on level; and
a connecting unit that connects the state memory unit with the transfer unit so that an electric charge is supplied to the first charge holding node based on a charge supply signal at on level,

the transfer unit includes:
a first output node configured to output the output signal;
a first output control transistor having: a control terminal connected to the first charge holding node; a first conducting terminal to which one of the plurality of clock signals included in the shift clock signal group is supplied; and a second conducting terminal connected to the first output node;
a first charge-holding node turn-on unit configured to receive an output signal outputted from the unit circuit of a previous stage as a set signal, and to change the level of the first charge holding node to on level based on the set signal; and
a first charge-holding node turn-off unit configured to receive an output signal outputted from the unit circuit of a succeeding stage as a reset signal, and to change the level of the first charge holding node to off level based on the reset signal,

the state memory unit includes:
a second output node configured to output the charge supply signal;
a second output control transistor having: a control terminal connected to the second charge holding node; a first conducting terminal to which the first control clock signal is supplied; and a second conducting terminal connected to the second output node;
a second charge-holding node turn-on unit configured to receive an output signal outputted from the unit circuit of the previous stage as the set signal, and to change the level of the second charge holding node to on level based on the set signal; and
a second charge-holding node turn-off unit configured to receive an output signal outputted from the unit circuit of the succeeding stage as the reset signal, and to change the level of the second charge holding node to off level based on the reset signal, and

clock operation of the first control clock signal is performed when clock operation of the shift clock signal group is suspended.

According to such a configuration, a state of the first charge holding node within the transfer unit when the suspension of scanning is performed is held in the state memory unit. Accordingly, even if charge leakage occurs at the thin film transistor within the transfer unit of the unit circuit during the suspension period in which the scanning is suspended, an electric charge is supplied to the first charge holding node based on the clock operation of the first control clock signal every predetermined period throughout the suspension period. Therefore, a level of the first charge holding node is maintained at a desired level throughout the suspension period. As a result, the scanning is normally restarted from the suspension stage (stage corresponding to the scanning stop position) after the suspension period is over. As described above, it is possible to realize a shift register capable of performing the suspension of scanning at any stage without causing an abnormal operation.

These and other objects, features, aspects, and effects of the present invention may become more apparent from the following detailed description of the present invention with reference to the appended drawings.

### BRIEF DESCRIPTION OF THE DRAWINGS

FIG. 1 is a diagram illustrating a schematic configuration of a unit circuit in a first embodiment.

FIG. 2 is a block diagram illustrating an overall configuration of an active matrix-type liquid crystal display device according to the first embodiment.

FIG. 3 is a block diagram for illustration of a configuration of a gate driver according to the first embodiment.

FIG. 4 is a block diagram illustrating a configuration of a shift register within the gate driver according to the first embodiment.

FIG. 5 is a signal waveform diagram for illustration of an operation of the gate driver according to the first embodiment.

FIG. 6 is a circuit diagram illustrating a specific configuration of a state memory unit within the unit circuit according to the first embodiment.

FIG. 7 is a circuit diagram illustrating a specific configuration of a transfer unit within the unit circuit according to the first embodiment.

FIG. 8 is a signal waveform diagram for illustration of one example of an operation at a latch stage when suspension of scanning is performed according to the first embodiment.

FIG. 9 is a signal waveform diagram for illustration of one example of an operation at stages other than the latch stage when suspension of scanning is performed according to the first embodiment.

FIG. 10 is a signal waveform diagram for illustration of one example of an operation at the latch stage when suspension of scanning is not performed according to the first embodiment.

FIG. 11 is a signal waveform diagram for illustration of one example of an operation at stages other than the latch stage when suspension of scanning is not performed according to the first embodiment.

FIG. 12 is a signal waveform diagram for illustration of an operation of a transfer unit when suspension of scanning is not performed according to the first embodiment.

FIG. 13 is a signal waveform diagram for illustration of an operation of a transfer unit when suspension of scanning is performed according to the first embodiment.

FIG. 14 is a signal waveform diagram for illustration of the fact that a potential at a first node is maintained at high level, according to the first embodiment.

FIG. 15 is a signal waveform diagram obtained in simulation in which a K-th stage is taken as a suspension stage, according to the first embodiment.

FIG. 16 is a signal waveform diagram obtained in simulation in which the K-th stage is taken as a suspension stage, according to the first embodiment.

FIG. 17 is a signal waveform diagram obtained in simulation in which the K-th stage is taken as a suspension stage, according to the first embodiment.

FIG. 18 is a signal waveform diagram obtained in simulation in which the K-th stage is taken as a suspension stage, according to the first embodiment.

FIG. 19 is a signal waveform diagram obtained in simulation in which the K-th stage is taken as a suspension stage, according to the first embodiment.

FIG. 20 is a diagram for illustration of an effect according to the first embodiment.

FIG. 21 is a diagram illustrating a schematic configuration of a unit circuit according to a modified example of the first embodiment.

FIG. 22 is a signal waveform diagram illustrating one example of an operation according to the modified example of the first embodiment.

FIG. 23 is a signal waveform diagram for illustration of one example of an operation according to a second embodiment.

FIG. 24 is a signal waveform diagram for illustration of another example of an operation according to the second embodiment.

FIG. 25 is a signal waveform diagram for illustration of timing at which a control clock signal CKX first rises, according to the second embodiment.

FIG. 26 is a signal waveform diagram for illustration of timing at which the control clock signal CKX first rises, according to the second embodiment.

FIG. 27 is a signal waveform diagram for illustration of timing at which the control clock signal CKX finally falls, according to the second embodiment.

FIG. 28 is a signal waveform diagram for illustration of timing at which the control clock signal CKX finally falls, according to the second embodiment.

FIG. 29 is a circuit diagram illustrating an example of a configuration of a conventional unit circuit.

FIG. 30 is a diagram for illustration of the fact that an abnormal operation occurs when scanning is restarted after scanning is suspended, regarding conventional example.

### DETAILED DESCRIPTION OF PREFERRED EMBODIMENTS

Hereinafter, embodiments will be described. In the following description, a gate terminal (gate electrode) of a thin film transistor corresponds to a control terminal, a drain terminal (drain electrode) thereof corresponds to a first conducting terminal, and a source terminal (source electrode) thereof corresponds to a second conducting terminal. Further, in this regard, while one of drain and source with a higher potential is called drain regarding an n-channel type transistor, in the description herein, one is defined as drain, and the other is defined as source, and therefore a source potential can be higher than a drain potential.

### 1. First Embodiment

### 1.1 Overall Configuration and General Operation

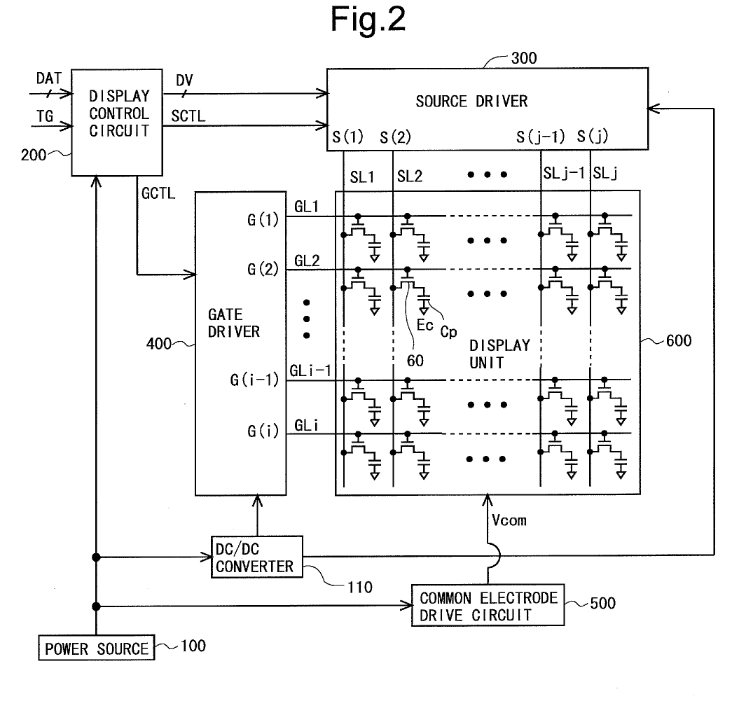

FIG. 2 is a block diagram illustrating an overall configuration of an active matrix-type liquid crystal display device according to a first embodiment. As shown in FIG. 2, this liquid crystal display device includes a power source 100, a DC/DC converter 110, a display control circuit 200, a source driver (video signal line drive circuit) 300, a gate driver (scanning signal line drive circuit) 400, a common electrode drive circuit 500, and a display unit 600. In this embodiment, the gate driver 400 and the display unit 600 are provided on the same substrate (a TFT substrate which is one of two substrates that constitute a liquid crystal panel). Specifically, the gate driver 400 according to this embodiment is a monolithic gate driver. In this embodiment, it is assumed that a liquid crystal panel that constitutes the display unit 600 is combined in one piece with a touch panel. However, the touch panel will not be described nor shown in the drawings, as it does not directly relate to the present invention.

The display unit 600 is provided with a plurality of (j) source bus lines (video signal lines) SL1-SLj, a plurality of (i) gate bus lines (scanning signal lines) GL1-GLi, and a plurality of (i×j) pixel formation portions respectively disposed at intersections between the plurality of source bus lines SL1-SLj and the plurality of gate bus lines GL1-GLi. The plurality of pixel formation portions are arranged in a matrix and constitute a pixel array. Each of the pixel formation portions includes: a thin film transistor (TFT) 60, which is a switching element, having a gate terminal connected to one of the gate bus lines that passes through a corresponding intersection and a source terminal connected to one of the source bus lines that passes through the same intersection; a pixel electrode connected to a drain terminal of the thin film transistor 60; a common electrode Ec which is a counter electrode commonly provided for the plurality of pixel formation portions; and a liquid crystal layer commonly provided for the plurality of pixel formation portions and sandwiched between the pixel electrode and the common electrode Ec. Further, a pixel capacitance Cp is configured by a liquid crystal capacitance formed by the pixel electrode and the common electrode Ec. In general, an auxiliary capacitance is provided in parallel with the liquid crystal capacitance in order to ensure that a charge is held by the pixel capacitance Cp. However, the auxiliary capacitance will not be described nor shown in the drawings, as it does not directly relate to the present invention. Moreover, the thin film transistor 60 in this embodiment is an n-channel type.

In the meantime, examples of the thin film transistor 60 to be employed include: a thin film transistor in which amorphous silicon is used for a semiconductor layer (a-Si TFT); a thin film transistor in which microcrystalline silicon is used for a semiconductor layer; a thin film transistor in which oxide semiconductor is used for a semiconductor layer (oxide TFT); and a thin film transistor in which low-temperature polysilicon is used for a semiconductor layer (LTPS-TFT). As the oxide TFT, for example, a thin film transistor having an oxide semiconductor layer including In—Ga—Zn—O-based semiconductor (e.g., indium gallium zinc oxide) may be employed. These also apply to a thin film transistor within the gate driver 400.

The power source 100 supplies a predetermined power-supply voltage to the DC/DC converter 110, the display control circuit 200, and the common electrode drive circuit 500. The DC/DC converter 110 generates, from the power-supply voltage, direct voltages (a direct power-supply voltage VDD and a direct power-supply voltage VSS) for operating the source driver 300 and the gate driver 400, and supplies the generated voltages to the source driver 300 and the gate driver 400. The common electrode drive circuit 500 supplies a common electrode drive voltage Vcom to the common electrode Ec.

The display control circuit 200 receives an image signal DAT and a group of timing signals TG, such as a horizontal synchronization signal and a vertical synchronization signal, that are supplied from outside, and outputs a digital video signal DV, a source control signal SCTL for controlling an operation of the source driver 300, and a gate control signal GCTL for controlling an operation of the gate driver 400. The source control signal SCTL includes signals such as a source start pulse signal, a source clock signal, and a latch strobe signal. The gate control signal GCTL includes signals such as a gate start pulse signal and a gate clock signal.

The source driver 300 applies driving video signals S(1)-S(j) to the source bus lines SL1-SLj, based on the digital video signal DV and the source control signal SCTL transmitted from a display control unit 100. At this time, at timing at which a pulse of the source clock signal is generated, the source driver 300 sequentially holds digital video signals DV each indicating a voltage to be applied to each of the source bus lines SL. Then, at timing at which a pulse of the latch strobe signal is generated, the digital video signals DV that are being held are converted into analog voltages. The converted analog voltages are applied to all of the source bus lines SL1-SLj at once as the driving video signals S(1)-S(j).

The gate driver 400 repeats application of the active scanning signals G(1)-G(i) to the respective gate bus lines GL1-GLi with a vertical scanning period as a cycle, based on the gate control signal GCTL transmitted from the display control unit 100. Specifically, the gate driver 400 performs scanning of the gate bus lines GL1-GLi. However, suspension of scanning is performed when processing for the touch panel is performed. Details of the gate driver 400 will be described later.

As described above, by applying the driving video signals S(1)-S(j) to the source bus lines SL1-SLj, and by applying the scanning signals G(1)-G(i) to the gate bus lines GL1-GLi, an image based on the image signal DAT that is externally supplied is displayed on the display unit 600.

### 1.2 Gate Driver

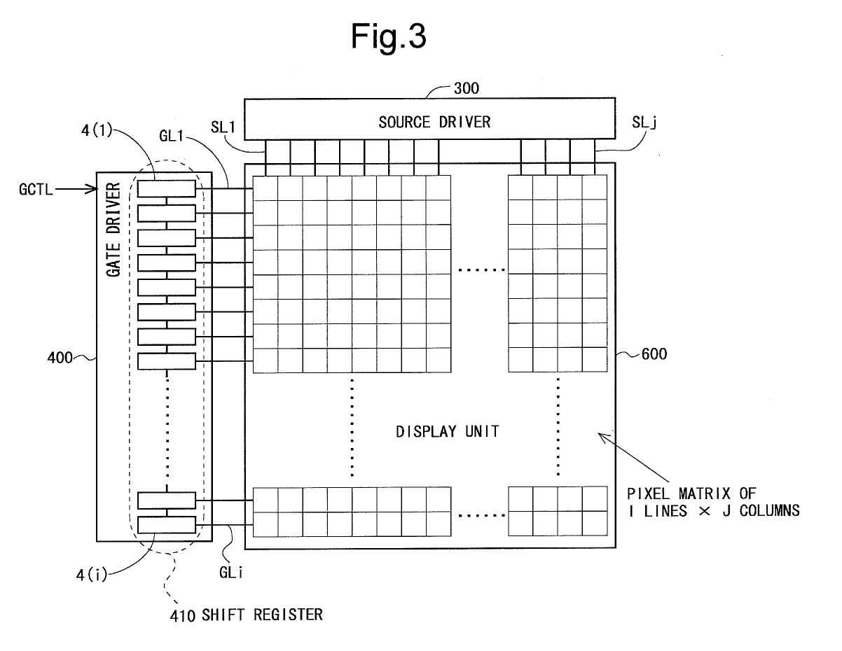

FIG. 3 is a block diagram for illustration of a configuration of the gate driver 400 according to this embodiment. As shown in FIG. 3, the gate driver 400 is configured by a shift register 410 constituted by a plurality of stages. The display unit 600 is provided with a pixel matrix of i lines×j columns, and each of the stages of the shift register 410 is provided so as to correspond to each lines of the pixel matrix one by one. Specifically, the shift register 410 includes i unit circuits 4(1)-4(i). Hereinafter, a configuration and an operation of the gate driver 400 will be described in detail.

### 1.2.1 Configuration and Operation of Entire Shift Register

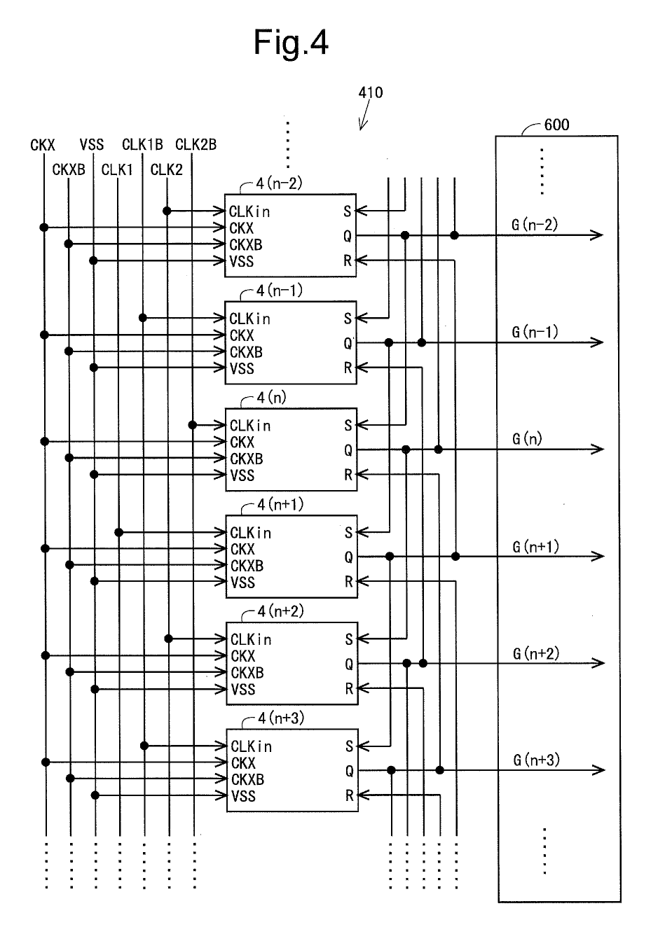

FIG. 4 is a block diagram illustrating a configuration of the shift register 410 within the gate driver 400. As described above, the shift register 410 is configured by i unit circuits 4(1)-4(i). In FIG. 4, the unit circuits 4(n−2)-4(n+3) from a (n−2)th stage to a (n+3)th stage are shown. In the following description, a reference number 4 is assigned to a unit circuit when i unit circuits 4(1)-4(i) are not required to be distinguished from each other.

To the shift register 410, as the gate control signal GCTL, a gate start pulse signal GSP (not shown in FIG. 4), a clear signal CLR (not shown in FIG. 4), gate clock signals CLK1, CLK1B, CLK2, and CLK2B, and control clock signals CKX and CKXB are supplied. Further, the direct power-supply voltage VSS is also supplied to the shift register 410. The gate clock signals CLK1, CLK1B, CLK2, and CLK2B are four-phase clock signals. Out of the four-phase clock signals, a clock signal inputted to each of the unit circuits 4 (hereinafter referred to as an “input clock signal”) is denoted by a reference number CLKin. The control clock signals CKX and CKXB are two-phase clock signals. In this embodiment, the gate clock signals CLK1, CLK1B, CLK2, and CLK2B realize a shift clock signal group, the control clock signal CKX realizes a first control clock signal, and the control clock signal CKXB realizes a second control clock signal.

Signals supplied to input terminals of each stage (each of the unit circuits 4) of the shift register 410 are as follows (see FIG. 4). Regarding the gate clock signal, the gate clock signal CLK2 is supplied to the unit circuit 4(n−2) of the (n−2)th stage, the gate clock signal CLK1B is supplied to the unit circuit 4(n−1) of the (n−1)th stage, the gate clock signal CLK2B is supplied to the unit circuit 4(n) of the n-th stage, and the gate clock signal CLK1 is supplied to the unit circuit 4(n+1) of the (n+1)th stage. Such a configuration is repeated every 4 stages for all stages throughout the shift register 410. Here, phases of the gate clock signal CLK1 and the gate clock signal CLK1B are displaced by 180 degrees, phases of the gate clock signal CLK2 and the gate clock signal CLK2B are displaced by 180 degrees, and a phase of the gate clock signal CLK1 is ahead of a phase of the gate clock signal CLK2 by 90 degrees. Further, for a unit circuit 4(k) of any stage (k-th stage, here, k is an integer no smaller than 1 and no greater than i), an output signal Q(k−2) outputted from a unit circuit 4(k−2) that is two stages before is supplied as a set signal S, an output signal Q(k+3) outputted from a unit circuit 4(k+3) that is three stages after is supplied as a reset signal R. The control clock signals CKX and CKXB and the direct power-supply voltage VSS are commonly supplied to all of the unit circuits 4(1)-4(i).

From an output terminal of each stage (each of the unit circuits 4) of the shift register 410, an output signal Q is outputted (see FIG. 4). The output signal Q outputted from any stage (k-th stage, here, k is an integer no smaller than 1 and no greater than i) is supplied to a gate bus line GL(k) as a scanning signal G(k), as well as to the unit circuit 4(k−3) three stages before as the reset signal R, and to the unit circuit 4(k+2) two stages after as the set signal S.

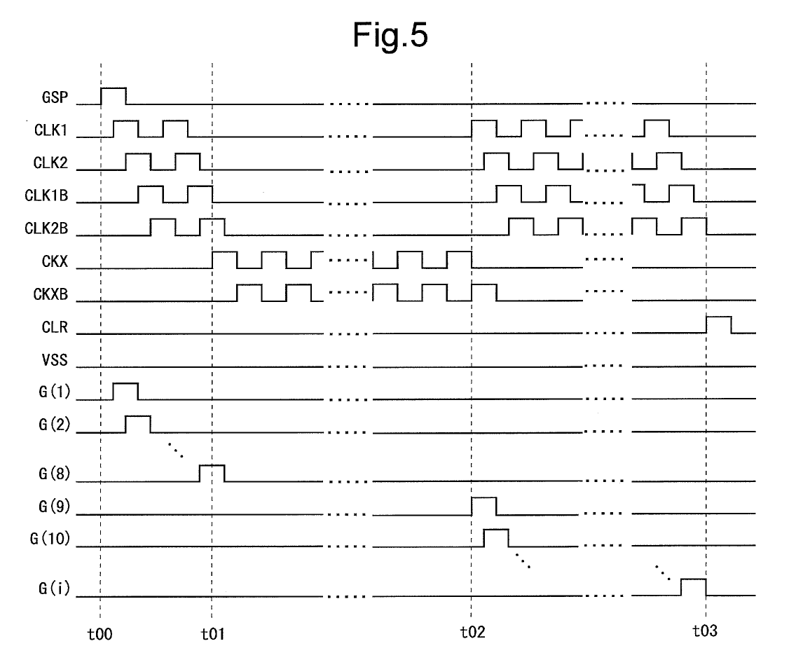

FIG. 5 is a signal waveform diagram for illustration of an operation of the gate driver 400. In the above configuration, when a pulse of the gate start pulse signal GSP is supplied to the shift register 410 at a time point t00, based on a clock operation of the gate clock signals CLK1, CLK2, CLK1B, and CLK2B, a shift pulse included in the output signal Q outputted from each of the unit circuits 4 is transferred sequentially from the unit circuit 4(1) of a first stage to the unit circuit 4(i) of an i-th stage (that is, a shift operation is performed). Then, in response to the transfer of the shift pulse, the output signal Q outputted from each of the unit circuits 4 is sequentially turned to high level. With this, as shown in FIG. 5, the scanning signals G(1)-G(i) that are sequentially turned to high level (active) for a predetermined period are supplied to the gate bus lines GL1-GLi within the display unit 600. Specifically, i gate bus lines GL1-GLi are sequentially in a selected state.

In the meantime, in this embodiment, suspension of scanning is allowed. In the example shown in FIG. 5, a period from a time point t01 to a time point t02 is a suspension period in which scanning is suspended. During the suspension period, the clock operation of the gate clock signals CLK1, CLK2, CLK1B, and CLK2B is stopped, and a clock operation of the control clock signals CKX and CKXB is performed. By such an operation being performed during the suspension period and each of the unit circuits 4 being configured in a manner later described, the scanning is restarted when the suspension period is over as shown in FIG. 5. Here, during the suspension period, processing for the touch panel (for example, processing for detecting a touch position) is performed.

### 1.2.2 Unit Circuit

### 1.2.2.1 Outline

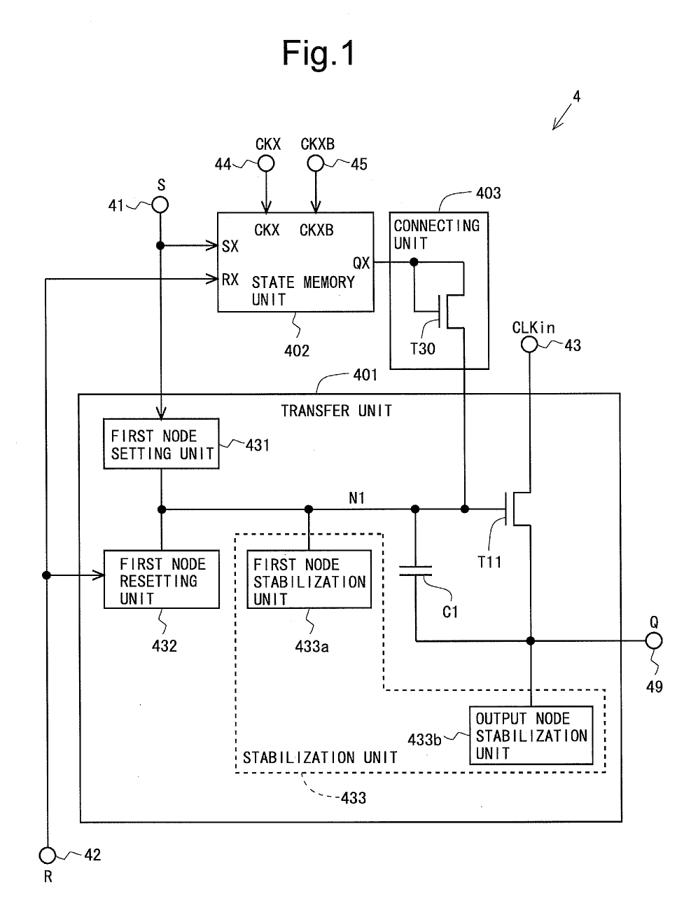

FIG. 1 is a diagram illustrating a schematic configuration of the unit circuit 4 according to this embodiment. As shown in FIG. 1, the unit circuit 4 in this embodiment is configured by a transfer unit 401, a state memory unit 402, and a connecting unit 403. The unit circuit 4 includes, in addition to an input terminal for the direct power-supply voltage VSS, an input terminal 41 for receiving the set signal S, an input terminal 42 for receiving the reset signal R, an input terminal 43 for receiving an input clock signal CLKin, an input terminal 44 for receiving the control clock signal CKX, an input terminal 45 for receiving the control clock signal CKXB, and an output terminal 49 for outputting the output signal Q. The transfer unit 401 includes a thin film transistor T11, a capacitor (capacitative element) C1, a first node N1, a first node setting unit 431, a first node resetting unit 432, and a stabilization unit 433. The stabilization unit 433 includes a first node stabilization unit 433a and an output node stabilization unit 433b. The connecting unit 403 includes a thin film transistor T30. Detailed configurations of the transfer unit 401 and the state memory unit 402 will be described later.

The first node setting unit 431 changes a potential of the first node N1 to high level, when the set signal S is at high level. The first node resetting unit 432 changes the potential of the first node N1 to low level, when the reset signal R is at high level. The first node stabilization unit 433a pulls the potential of the first node N1 to low level during a period in which the potential of the first node N1 is to be maintained at low level, so that an output of an abnormal pulse due to an increase of the potential of the first node N1 is prevented. The output node stabilization unit 433b pulls a potential of the output terminal 49 to low level during a period in which the potential of the output terminal 49 is to be maintained at low level, so that an output of an abnormal pulse is prevented.

For the thin film transistor T30 within the connecting unit 403, the output signal QX from the state memory unit 402 is supplied to a gate terminal and a drain terminal, and a source terminal is connected to the first node N1 within the transfer unit 401. With such a configuration, the thin film transistor T30 is turned to an on state when the output signal QX is at high level. Then, when the thin film transistor T30 is turned to the on state, an electric charge is supplied to the first node N1 based on the high-level output signal QX. In this manner, the connecting unit 403 connects the state memory unit 402 and the transfer unit 401, so that an electric charge based on the high-level (on-level) output signal QX outputted from the state memory unit 402 is supplied to the first node N1 within the transfer unit 401. Here, in this embodiment, a charge supply signal is realized by the output signal QX.

### 1.2.2.2 Configuration of State Memory Unit

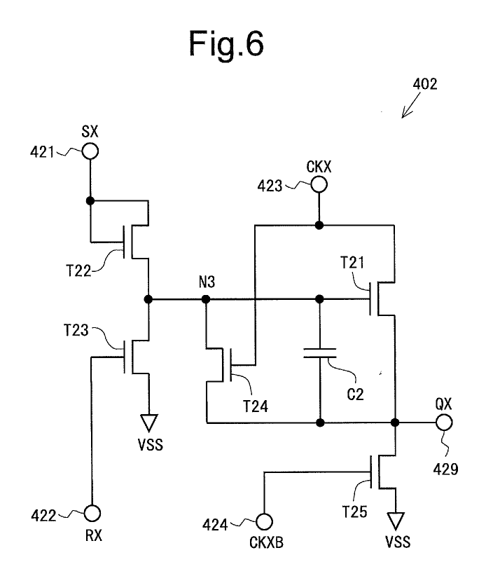

FIG. 6 is a circuit diagram illustrating a specific configuration of the state memory unit 402 within the unit circuit 4. As shown in FIG. 6, the state memory unit 402 includes five thin film transistors T21-T25 and a capacitor (capacitative element) C2. Further, the state memory unit 402 includes, in addition to an input terminal for the direct power-supply voltage VSS, four input terminals 421-424 and an output terminal 429. Here, an input terminal for receiving the set signal SX is denoted by a reference number 421, an input terminal for receiving the reset signal RX is denoted by a reference number 422, an input terminal for receiving the control clock signal CKX is denoted by a reference number 423, and an input terminal for receiving the control clock signal CKXB is denoted by a reference number 424.

It should be noted that while the set signal S supplied to the unit circuit 4 and the set signal SX supplied to the state memory unit 402 are the same signal, the set signal supplied to the state memory unit 402 is denoted by a reference number SX for convenience. Further, the input terminal 421 is substantially the same terminal as the input terminal 41 shown in FIG. 1, the input terminal 422 is substantially the same terminal as the input terminal 42 shown in FIG. 1, the input terminal 423 is substantially the same terminal as the input terminal 44 shown in FIG. 1, and the input terminal 424 is substantially the same terminal as the input terminal 45 shown in FIG. 1.

Next, connection relationship between components within the state memory unit 402 will be described. A gate terminal of the thin film transistor T21, a source terminal of the thin film transistor T22, a drain terminal of the thin film transistor T23, a drain terminal of the thin film transistor T24, and one end of the capacitor C2 are connected to each other. Here, an area (wiring) in which these are connected is referred to as a “third node”. The third node is denoted by a reference number N3.

Regarding the thin film transistor T21, the gate terminal is connected to the third node N3, a drain terminal is connected to the input terminal 423, and a source terminal is connected to the output terminal 429. Regarding the thin film transistor T22, a gate terminal and a drain terminal are connected to the input terminal 421 (that is, diode-connected), and the source terminal is connected to the third node N3. Regarding the thin film transistor T23, a gate terminal is connected to the input terminal 422, the drain terminal is connected to the third node N3, and a source terminal is connected to the input terminal for the direct power-supply voltage VSS. Regarding the thin film transistor T24, a gate terminal is connected to the input terminal 423, the drain terminal is connected to the third node N3, and a source terminal is connected to the output terminal 429. Regarding the thin film transistor T25, a gate terminal is connected to the input terminal 424, a drain terminal is connected to the output terminal 429, and a source terminal is connected to the input terminal for the direct power-supply voltage VSS. Regarding the capacitor C2, the one end is connected to the third node N3, and the other end is connected to the output terminal 429.

Next, functions of the components will be described. The thin film transistor T21 supplies a potential of the control clock signal CKX to the output terminal 429, when the potential of the third node N3 is at high level. The thin film transistor T22 changes a potential of the third node N3 to high level, when the set signal SX is at high level. The thin film transistor T23 changes the potential of the third node N3 to low level, when the reset signal RX is at high level. The thin film transistor T24 makes the potential of the third node N3 and the potential of the output terminal 429 (the potential of the output signal QX) be the same, when the control clock signal CKX is at high level. The thin film transistor T25 changes a potential of the output terminal 429 (the potential of the output signal QX) to low level, when the control clock signal CKXB is at high level. The capacitor C2 serves as a bootstrap capacitance for increasing the potential of the third node N3.

Here, in this embodiment, the third node N3 realizes a second charge holding node, and the output terminal 429 realizes a second output node. Further, the thin film transistor T21 realizes a second output control transistor, the thin film transistor T22 realizes a second charge-holding node turn-on unit and a second charge-holding node turn-on transistor, the thin film transistor T23 realizes a second charge-holding node turn-off unit and a second charge-holding node turn-off transistor, the thin film transistor T24 realizes a second charge-holding node stabilization transistor, and the thin film transistor T25 realizes a second output-node turn-off transistor.

### 1.2.2.3 Configuration of Transfer Unit

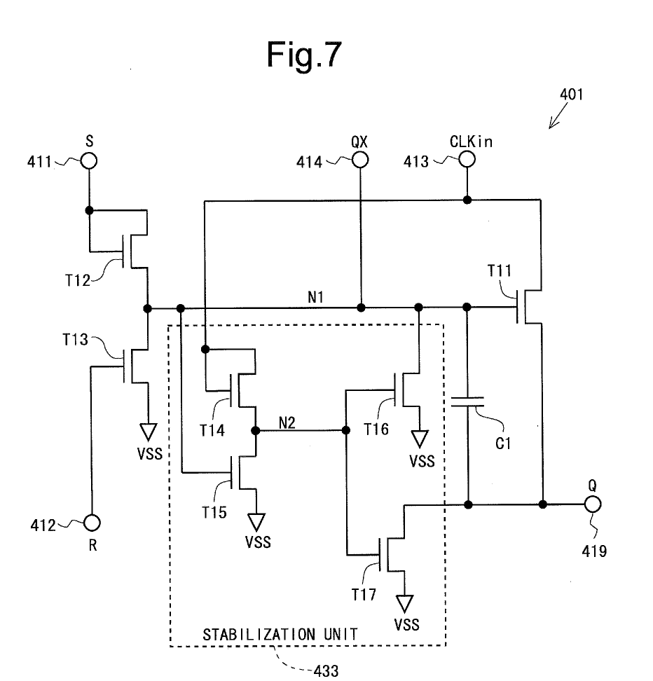

FIG. 7 is a circuit diagram illustrating a specific configuration of the transfer unit 401 within the unit circuit 4. As shown in FIG. 7, the transfer unit 401 includes seven thin film transistors T11-T17 and a capacitor (capacitative element) C1. Further, the transfer unit 401 includes, in addition to the input terminal for the direct power-supply voltage VSS, four input terminals 411-414 and an output terminal 419. Here, an input terminal for receiving the set signal S is denoted by a reference number 411, an input terminal for receiving the reset signal R is denoted by a reference number 412, an input terminal for receiving the input clock signal CLKin is denoted by a reference number 413, and an input terminal for receiving the output signal QX from the state memory unit 402 is denoted by a reference number 414.

Here, the input terminal 411 is substantially the same terminal as the input terminal 41 shown in FIG. 1, the input terminal 412 is substantially the same terminal as the input terminal 42 shown in FIG. 1, the input terminal 413 is substantially the same terminal as the input terminal 43 shown in FIG. 1, and the output terminal 419 is substantially the same terminal as the output terminal 49 shown in FIG. 1.

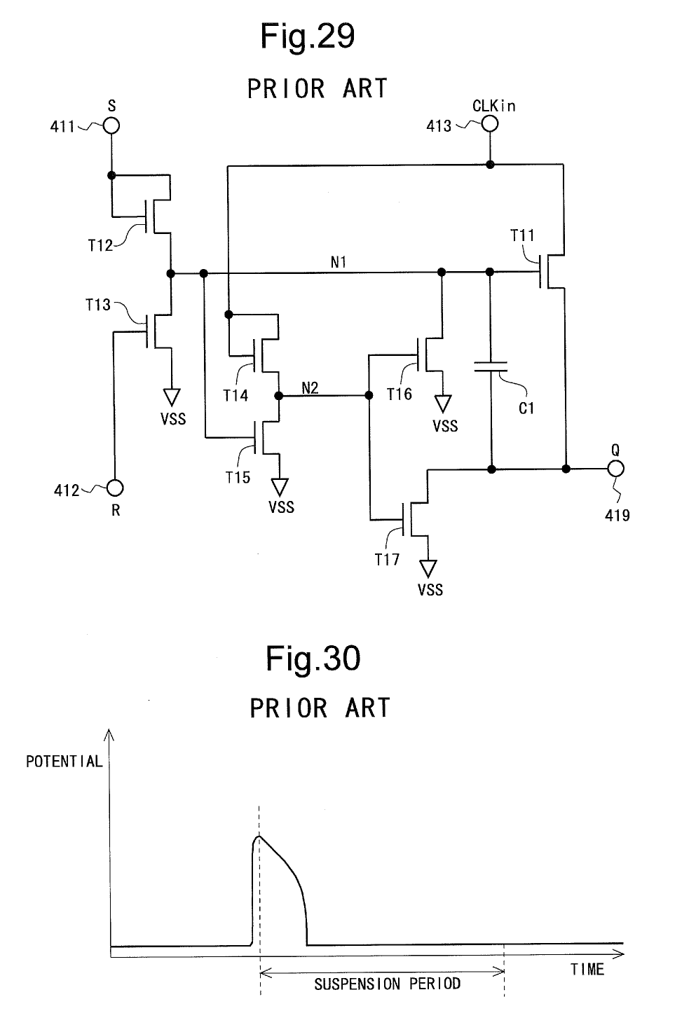

In the meantime, comparing FIG. 7 with FIG. 29, it can be seen that a configuration in which the output signal QX from the state memory unit 402 is supplied to the first node N1 in the conventional unit circuit (FIG. 29) corresponds to the configuration of the transfer unit 401 in this embodiment.

Next, connection relationship between components within the transfer unit 401 will be described. A gate terminal of the thin film transistor T11, a source terminal of the thin film transistor T12, a drain terminal of the thin film transistor T13, a gate terminal of the thin film transistor T15, a drain terminal of the thin film transistor T16, the input terminal 414, and one end of the capacitor C1 are connected to each other via the first node N1. A source terminal of the thin film transistor T14, a drain terminal of the thin film transistor T15, a gate terminal of the thin film transistor T16, and a gate terminal of the thin film transistor T17 are connected to each other. Here, an area (wiring) in which these are connected is referred to as a “second node”. The second node is denoted by a reference number N2.

Regarding the thin film transistor T11, the gate terminal is connected to the first node N1, a drain terminal is connected to the input terminal 413, and a source terminal is connected to the output terminal 419. Regarding the thin film transistor T12, a gate terminal and a drain terminal are connected to the input terminal 411 (that is, diode-connected), and the source terminal is connected to the first node N1. Regarding the thin film transistor T13, a gate terminal is connected to the input terminal 412, the drain terminal is connected to the first node N1, and a source terminal is connected to the input terminal for the direct power-supply voltage VSS. Regarding the thin film transistor T14, a gate terminal and a drain terminal are connected to the input terminal 413 (that is, diode-connected), and the source terminal is connected to the second node N2. Regarding the thin film transistor T15, the gate terminal is connected to the first node N1, the drain terminal is connected to the second node N2, and a source terminal is connected to the input terminal for the direct power-supply voltage VSS. Regarding the thin film transistor T16, the gate terminal is connected to the second node N2, the drain terminal is connected to the first node N1, and a source terminal is connected to the input terminal for the direct power-supply voltage VSS. Regarding the thin film transistor T17, the gate terminal is connected to the second node N2, a drain terminal is connected to the output terminal 419, and a source terminal is connected to the input terminal for the direct power-supply voltage VSS. Regarding the capacitor C1, the one end is connected to the first node N1, and the other end is connected to the output terminal 419.

Next, functions of the components will be described. The thin film transistor T11 supplies a potential of the input clock signal CLKin to the output terminal 419, when the potential of the first node N1 is at high level. The thin film transistor T12 changes the potential of the first node N1 to high level, when the set signal S is at high level. The thin film transistor T13 changes the potential of the first node N1 to low level, when the reset signal R is at high level. The thin film transistor T14 changes a potential of the second node N2 to high level, when the input clock signal CLKin is at high level. The thin film transistor T15 changes the potential of the second node N2 to low level, when the potential of the first node N1 is at high level. The thin film transistor T16 changes the potential of the first node N1 to low level, when the potential of the second node N2 is at high level. The thin film transistor T17 changes a potential of the output terminal 419 (a potential of the output signal Q) to low level, when the potential of the second node N2 is at high level. The capacitor C1 serves as a bootstrap capacitance for increasing the potential of the first node N1.

Here, in this embodiment, the first node N1 realizes a first charge holding node, and the output terminal 419 realizes a first output node. Further, the thin film transistor T11 realizes a first output control transistor, the thin film transistor T12 realizes a first charge-holding node turn-on unit, and the thin film transistor T13 realizes a first charge-holding node turn-off unit.

### 1.2.2.4 Operation of State Memory Unit

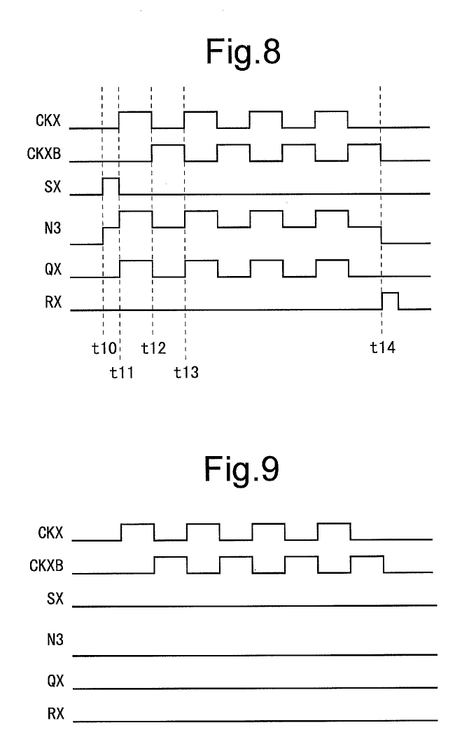

Next, an operation of the state memory unit 402 will be described with reference to FIG. 8 to FIG. 11. First, an operation when suspension of scanning is performed is described, and then an operation when the suspension of scanning is not performed is described. In the following description, out of the plurality of stages (i stages) that constitute the shift register 410, stages for which it is necessary to prevent a decrease of the potential of the first node N1 due to charge leakage during the suspension period are referred to as “latch stages”, for convenience. The latch stages include a stage corresponds to a scanning stop position (hereinafter referred to as a “suspension stage”) and stages near the suspension stage.

FIG. 8 is a signal waveform diagram for illustration of one example of an operation at a latch stage when the suspension of scanning is performed. When the set signal SX changes from low level to high level at a time point t10, as the thin film transistor T22 is diode-connected as shown in FIG. 6, a pulse of the set signal SX turns the thin film transistor T22 to the on state, and the capacitor C2 is charged. With this, the potential of the third node N3 changes from low level to high level, and the thin film transistor T21 is turned to the on state.

Thereafter, when the control clock signal CKX changes from low level to high level at a time point t11, as the thin film transistor T21 is in the on state, the potential of the output terminal 429 increases as a potential of the input terminal 423 increases. Here, as the capacitor C2 is disposed between the third node N3 and the output terminal 429 as shown in FIG. 6, the potential of the third node N3 increases (the third node N3 is bootstrapped) as the potential of the output terminal 429 increases. As a result, a large voltage is applied to the gate terminal of the thin film transistor T21, and the potential of the output terminal 429 increases to a large extent. Specifically, the output signal QX is turned to high level. As a result, the thin film transistor T30 within the connecting unit 403 is turned to the on state, and an electric charge is supplied to the first node N1 within the transfer unit 401.

At a time point t12, the control clock signal CKX changes from high level to low level. With this, the potential of the output terminal 429 (the potential of the output signal QX) decreases as the potential of the input terminal 423 decreases. Further, at the time point t12, the control clock signal CKXB changes from low level to high level. With this, the thin film transistor T25 is turned to the on state, and the output signal QX is turned to low level. Then, the potential of the third node N3 decreases via the capacitor C2.

After a time point t13, based on the clock operation of the control clock signals CKX and CKXB, an operation that is the same as the operation at the time point t11 and the time point t12 is repeated. Specifically, regarding the potential of the third node N3, pull-up and pull-down are repeated taking a charging potential at the time point t10 as a starting point. At this time, as can be seen from FIG. 8, the output signal QX changes from low level to high level when the potential of the third node N3 is pulled up.

Thereafter, when the reset signal RX changes from low level to high level at a time point t14, the thin film transistor T23 is turned to the on state. With this, the potential of the third node N3 decreases down to low level. With this, in a period after the time point t14, the output signal QX is maintained at low level.

FIG. 9 is a signal waveform diagram for illustration of one example of an operation at stages other than the latch stages when the suspension of scanning is performed. As shown in FIG. 9, as the set signal SX is maintained at low level at the stages other than the latch stages, the potential of the third node N3 is maintained at low level. However, the potential of the third node N3 may fluctuate, due to the clock operation of the control clock signal CKX and a presence of a parasitic capacitance at the thin film transistor T21. Specifically, the potential of the output signal QX may increases unnecessarily. Therefore, the state memory unit 402 is provided with the thin film transistor T24 as shown in FIG. 6. By providing the thin film transistor T24, when the control clock signal CKX is at high level, the potential of the third node N3 is pulled to the same potential as the potential of the output terminal 429. Further, the thin film transistor T25 is turned to the on state, based on the control clock signal CKXB whose phase is opposite of that of the control clock signal CKX. As the potential of the output terminal 429 (the potential of the output signal QX) is turned to low level when the thin film transistor T25 is turned to the on state, an increase of the potential of the output signal QX due to accumulation of the electric charge is prevented.

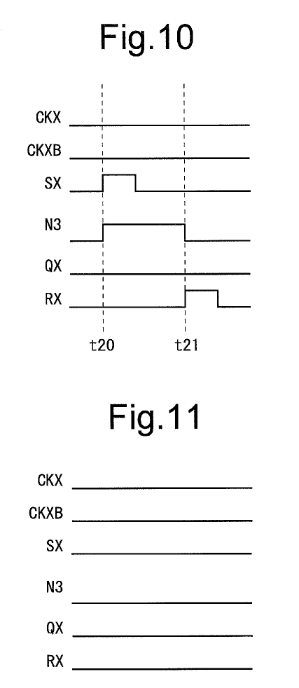

FIG. 10 is a signal waveform diagram for illustration of one example of an operation at the latch stage when the suspension of scanning is not performed. When the set signal SX changes from low level to high level at a time point t20, the thin film transistor T22 is turned to the on state, and the capacitor C2 is charged. With this, the potential of the third node N3 changes from low level to high level. When the suspension of scanning is not performed, the control clock signal CKX is maintained at low level as shown in FIG. 10. Accordingly, the potential of the input terminal 423 may not increase, and the output signal QX is maintained at low level. At a time point t21, the reset signal RX changes from low level to high level. With this, the thin film transistor T23 is turned to the on state, and the potential of the third node N3 is turned to low level.

FIG. 11 is a signal waveform diagram for illustration of one example of an operation at the stages other than the latch stages when the suspension of scanning is not performed. As shown in FIG. 11, as the set signal SX is maintained at low level at the stages other than the latch stages, the potential of the third node N3 is maintained at low level. Further, when the suspension of scanning is not performed, the control clock signals CKX and CKXB are also maintained at low level. Thus, as can be seen from FIG. 11, at the stages other than the latch stages, the state memory unit 402 is maintained in a suspended state.

### 1.2.2.5 Operation of Transfer Unit

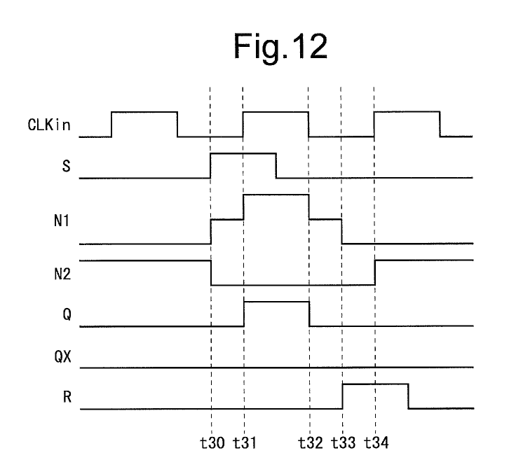

Next, an operation of the transfer unit 401 when the shift operation is performed will be described with reference to FIG. 12 to FIG. 14. First, an operation when the suspension of scanning is not performed is described (see FIG. 12). In a period before a time point t30, the set signal S is at low level, the potential of the first node N1 is at low level, the potential of the second node N2 is at high level, the output signal Q is at low level, the output signal QX from the state memory unit 402 is at low level, and the reset signal R is at low level. The input clock signal CLKin repeats high level and low level alternately. In the meantime, a parasitic capacitance is present at the thin film transistor T11 within the transfer unit 401. Accordingly, in the period before the time point t30, the potential of the first node N1 may fluctuate, due to the clock operation of the input clock signal CLKin and the presence of the parasitic capacitance at the thin film transistor T11. Therefore, the potential of the output terminal 419 (the potential of the output signal Q), that is, a potential of the scanning signal G supplied to the gate bus line GL may increase. However, in a period in which the potential of the second node N2 is maintained at high level, the thin film transistors T16 and T17 are maintained in the on state. Therefore, in the period before the time point t30, the thin film transistors T16 and T17 are maintained in the on state, and the potential of the first node N1 and the potential of the output terminal 419 (the potential of the output signal Q) are reliably maintained at low level. Thus, even if a noise due to the clock operation of the input clock signal CLKin is mixed into the first node N1, a potential of the corresponding scanning signal G may not increase. With this, occurrence of an abnormal operation due to the clock operation of the input clock signal CLKin may be prevented.

At the time point t30, the set signal S changes from low level to high level. As the thin film transistor T12 is diode-connected as shown in FIG. 7, a pulse of the set signal S turns the thin film transistor T12 to the on state, and the capacitor C1 is charged. With this, the potential of the first node N1 changes from low level to high level, and the thin film transistor T11 is turned to the on state. However, as the input clock signal CLKin is at low level at the time point t30, the output signal Q is maintained at low level. Further, by the potential of the first node N1 changing from low level to high level, the thin film transistor T15 is turned to the on state. With this, the potential of the second node N2 is turned to low level, and the thin film transistor T16 is turned to the off state. Here, during a period from the time point t30 to a time point t31, the reset signal R is maintained at low level. Therefore, the potential of the first node N1 may not decrease during this period.

At the time point t31, the input clock signal CLKin changes from low level to high level. At this time, as the thin film transistor T11 is in the on state, the potential of the output terminal 419 increases as a potential of the input terminal 413 increases. Here, as the capacitor C1 is disposed between the first node N1 and the output terminal 419 as shown in FIG. 7, the potential of the first node N1 increases (the first node N1 is bootstrapped) as the potential of the output terminal 419 increases. As a result, a large voltage is applied to the gate terminal of the thin film transistor T11, and the potential of the output signal Q increases up to a level that is sufficient for the gate bus line GL connected to the output terminal 419 of the transfer unit 401 to be in the selected state. Here, during a period from the time point t31 to a time point t32, the reset signal R is maintained at low level, and the potential of the second node N2 is maintained at low level. Therefore, the potential of the first node N1 and the potential of the output terminal 419 (the potential of the output signal Q) may not decrease during this period.

At the time point t32, the input clock signal CLKin changes from high level to low level. With this, the potential of the output terminal 49 (the potential of the output signal Q) decreases as the potential of the input terminal 413 decreases. When the potential of the output terminal 49 decreases, the potential of the first node N1 also decreases via the capacitor C1.

At a time point t33, the reset signal R changes from low level to high level. With this, the thin film transistor T13 is turned to the on state. As a result, the potential of the first node N1 decreases down to low level.

At a time point t34, the input clock signal CLKin changes from low level to high level. As the thin film transistor T14 is diode-connected as shown in FIG. 7, the potential of the second node N2 is turned to high level by the input clock signal CLKin changing from low level to high level. With this, the thin film transistors T16 and T17 are turned to the on state. Then, in a period after the time point t34, an operation that is the same as that in the period before the time point t30 is performed.

By the operation described above being performed by each of the unit circuits 4, the plurality of gate bus lines GL(1)-GL(i) provided for the liquid crystal display device sequentially become the selected state, and writing to the pixel capacitances is performed sequentially.

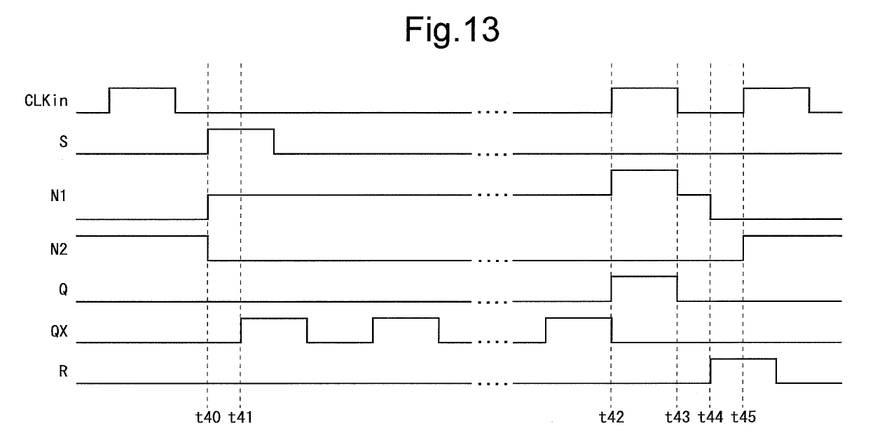

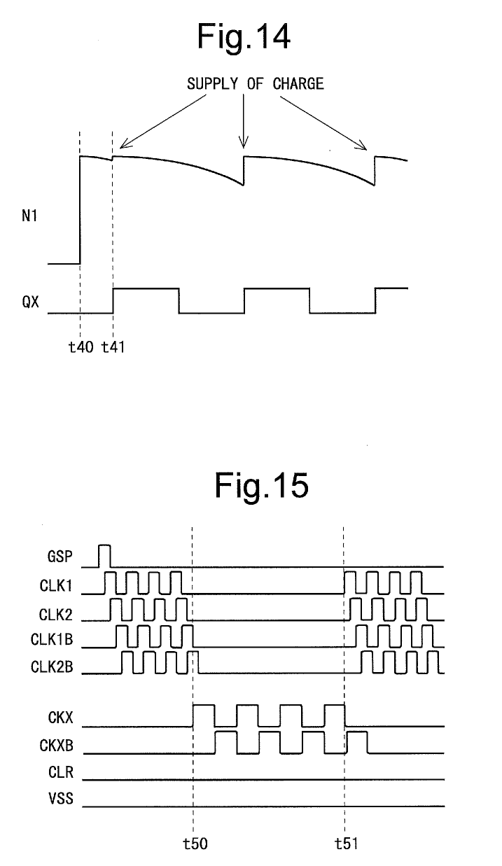

Next, an operation when the suspension of scanning is performed (that is, an operation of the suspension stage) will be described (see FIG. 13 and FIG. 14). Here, a period between a time point t41 and a time point t42 is assumed to be the suspension period. During a period before the time point t41, the same operation as in the period before the time point t31 in the case where the suspension of scanning is not performed (see FIG. 12) is performed.

In this case, the input clock signal CLKin is maintained at low level even at the time point t41. Instead, at the time point t41, the output signal QX from the state memory unit 402 changes from low level to high level. With this, an electric charge based on the output signal QX is supplied to the first node N1 via the input terminal 414.

In the period from the time point t41 to the time point t42, the output signal QX from the state memory unit 402 repeats high level and low level alternately. With this, an electric charge based on the output signal QX is supplied to the first node N1 via the input terminal 414, every time the output signal QX changes from low level to high level. Accordingly, as shown in FIG. 14, the potential of the first node N1 increases every time the output signal QX changes from low level to high level, even if the potential of the first node N1 decreases due to charge leakage at the thin film transistors T12, T13, and T16. Therefore, even if a charge leakage occurs at the thin film transistors T12, T13, and T16, the potential of the first node N1 is maintained at high level.

At the time point t42, when the input clock signal CLKin changes from low level to high level, an operation that is the same as that at the time point t31 in the case where the suspension of scanning is not performed (see FIG. 12) is performed. With this, the potential of the output signal Q increases up to a level that is sufficient for the gate bus line GL connected to the output terminal 419 of the transfer unit 401 to be in the selected state. In a period after a time point t43, an operation that is the same as that in the period after the time point t32 in the case where the suspension of scanning is not performed (see FIG. 12) is performed.

As described above, at the suspension stage, the potential of the first node N1 is maintained at high level throughout the suspension period. Then, after the suspension period is over, the output signal Q is turned to high level based on the clock operation of the input clock signal CLKin. In this manner, after the suspension period is over, the scanning is restarted from the suspension stage.

### 1.3 Effects

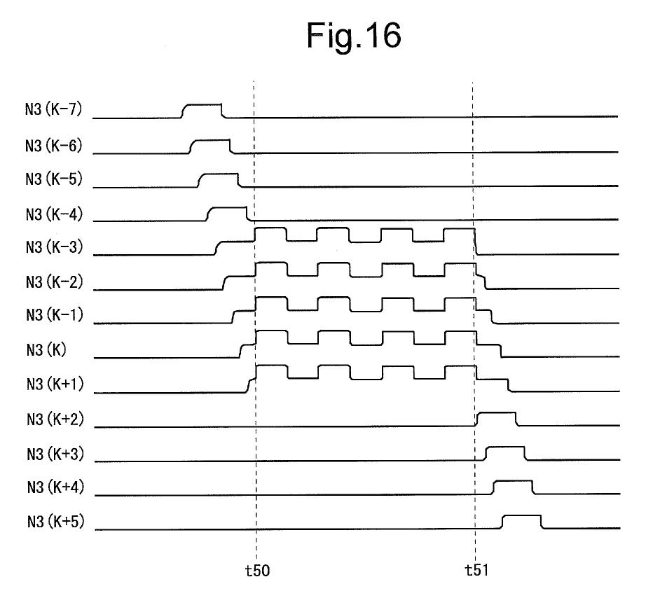

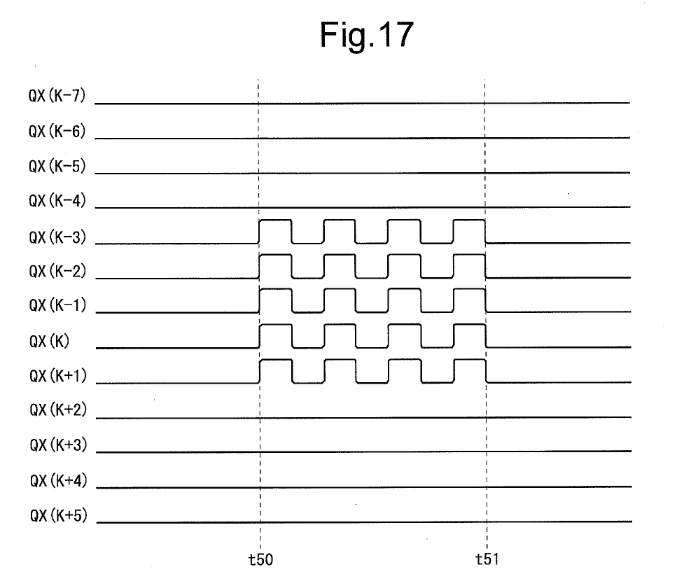

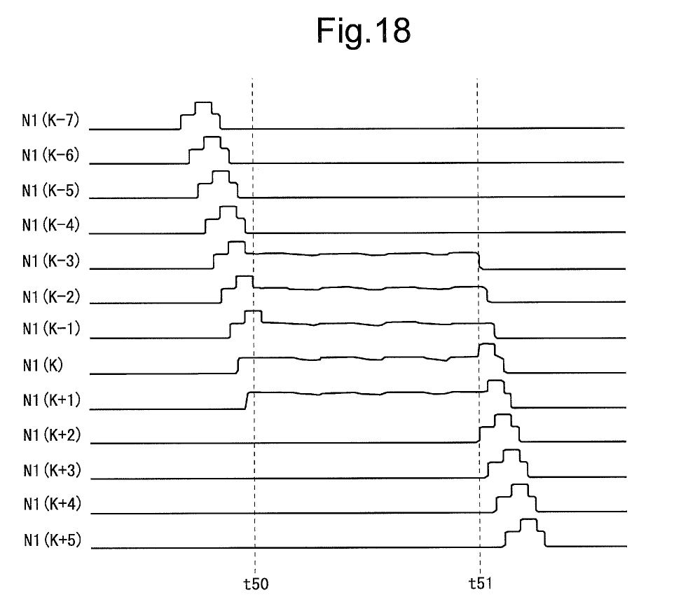

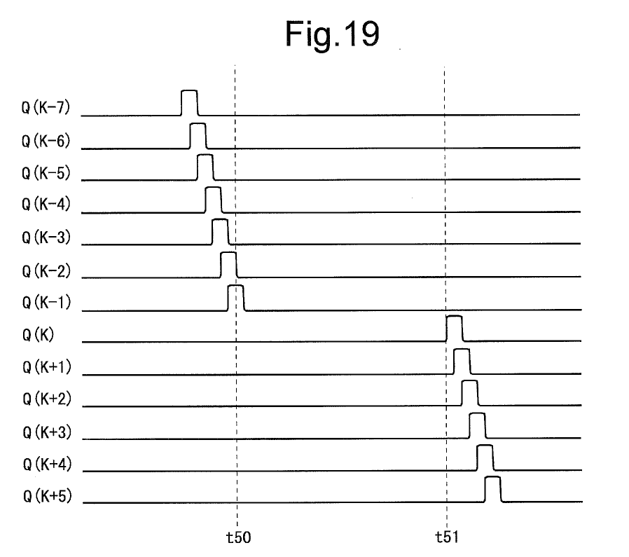

FIG. 15 to FIG. 19 are signal waveform diagrams obtained in simulation in which a K-th stage is taken as the suspension stage. FIG. 15 shows the waveform of various input signals. FIG. 16 shows the waveform of the potential of the third node N3 in stages near the suspension stage. FIG. 17 shows the waveform of the output signal QX in the stages near the suspension stage. FIG. 18 shows the waveform of the potential of the first node N1 in the stages near the suspension stage. FIG. 19 shows the waveform of the output signal Q in the stages near the suspension stage. Here, in FIG. 15 to FIG. 19, a period between a time point t50 to a time point t51 corresponds to the suspension period.

As shown in FIG. 16, throughout the suspension period, at the unit circuits 4(K−3) to 4(K+1) from a (K−3)-th stage to a (K+1)th stage, regarding the potential of the third node N3, pull-up and pull-down are repeated taking a charging potential as a starting point. With this, as shown in FIG. 17, throughout the suspension period, at the unit circuits 4(K−3) to 4(K+1) from the (K−3)-th stage to the (K+1)th stage, the output signal QX from the state memory unit 402 repeats a change from low level to high level and a change from high level to low level. Specifically, at the unit circuits 4(K−3) to 4(K+1) from the (K−3)-th stage to the (K+1)th stage, throughout the suspension period, an electric charge is supplied to the first node N1 within the transfer unit 401 every predetermined period. With this, as can be seen from FIG. 18, at the unit circuits 4(K−3) to 4(K+1) from the (K−3)-th stage to the (K+1)th stage, a decrease of the potential of the first node N1 during the suspension period is prevented. As a result, as can be seen from FIG. 19, the scanning is normally restarted from the suspension stage after the suspension period is over.

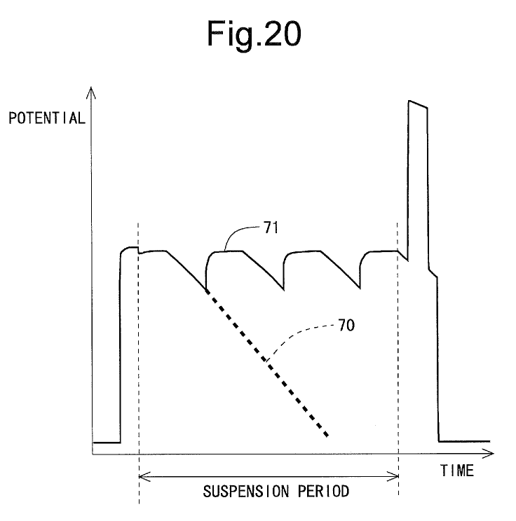

According to this embodiment, the unit circuit 4 that forms each of the stages of the shift register 410 within the gate driver 400 is configured by the transfer unit 401 having substantially the same configuration as that of the conventional unit circuit, the state memory unit 402 configured to store the state of the first node N1 within the transfer unit 401 when the suspension of scanning is performed, and the connecting unit 403 that connects the state memory unit 402 with the transfer unit 401 so that an electric charge based on the output signal QX from the state memory unit 402 is supplied to the first node N1. Accordingly, even if charge leakage occurs at the thin film transistors T12, T13, and T16 within the transfer unit 401 included in the unit circuit 4 during the suspension period by the suspension of scanning being performed, an electric charge is supplied to the first node N1 every predetermined period throughout the suspension period. Therefore, the potential of the first node N1 may not decrease during the suspension period as indicated by a heavy dotted line denoted by a reference number 70 in FIG. 20, the potential of the first node N1 is maintained at high level throughout the suspension period as indicated by a solid line denoted by a reference number 71 in FIG. 20. As a result, the scanning is normally restarted from the suspension stage after the suspension period is over. As described above, according to this embodiment, it is possible to realize a shift register capable of performing the suspension of scanning at an arbitrary stage without causing an abnormal operation.

Further, regarding each of the thin film transistors T21, T24, and T25 within the state memory unit 402 (see FIG. 6), bias voltage is applied only during the suspension period. In addition, as a duty ratio of the control clock signals CKX and CKXB is one-half, bias voltages are applied to the thin film transistors T21, T24, and T25 only during a substantially half of the suspension period. Therefore, a threshold shift of the thin film transistors T21, T24, and T25 (fluctuation of a threshold voltage) is suppressed, and an effect of increased duration of life may be obtained.

### 1.4 Modified Example

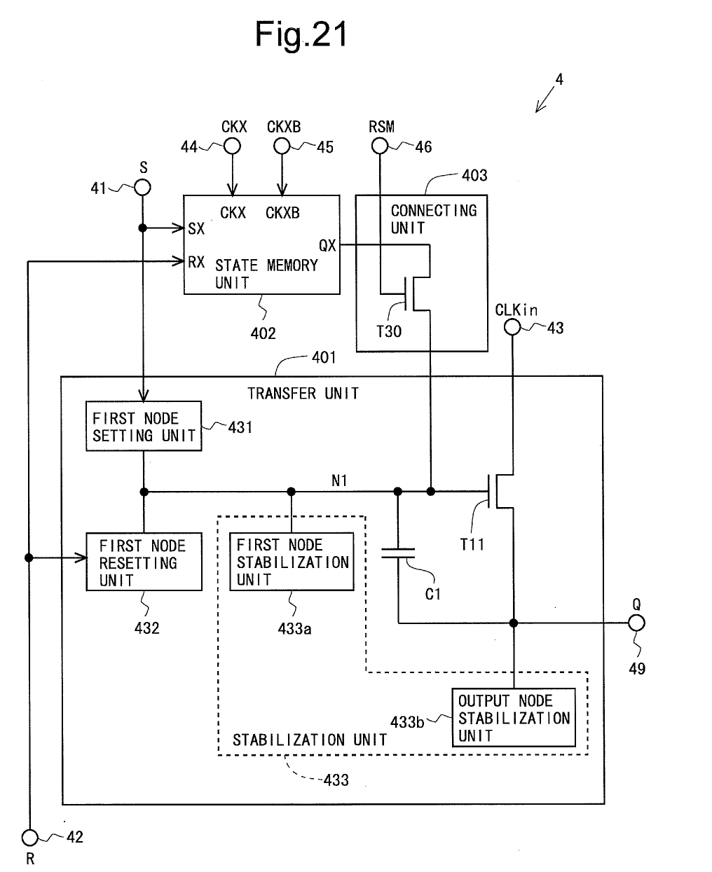

In the first embodiment, the thin film transistor T30 within the connecting unit 403 forming the unit circuit 4 is diode-connected. However, the present invention is not limited to this example, and as shown in FIG. 21, the configuration (configuration of this modified example) may be such that a control signal RSM is supplied from outside to the gate terminal of the thin film transistor T30. Specifically, according to this modified example, regarding the thin film transistor T30 within the connecting unit 403, the control signal RSM is supplied to the gate terminal, the output signal QX from the state memory unit 402 is supplied to the drain terminal, and the source terminal is connected to the first node N1 within the transfer unit 401.

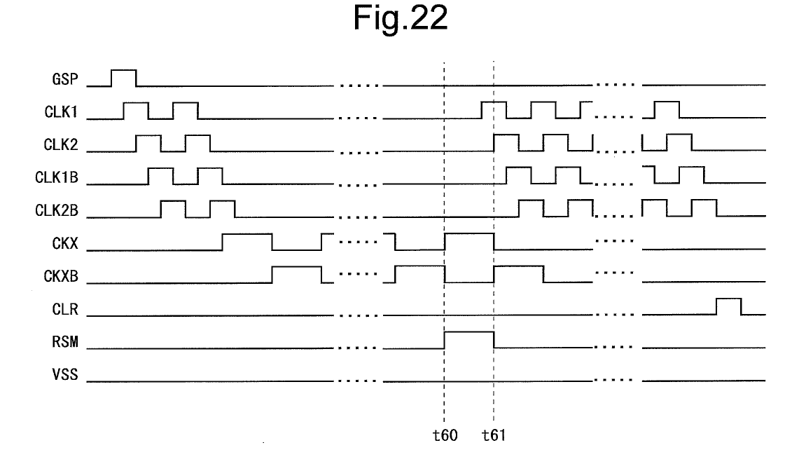

According to this modified example, it is possible to supply an electric charge based on the output signal QX to the first node N1 within the transfer unit 401 only at specific timing. In the first embodiment, an electric charge is supplied to the first node N1 every time the control clock signal CKX changes from low level to high level at the latch stages. However, according to this modified example, for example, as shown in FIG. 22, it is possible to supply an electric charge to the first node N1 only during a partial period (a period from a time point t60 to a time point t61).

### 2. Second Embodiment

### 2.1 Outline and Configuration

A second embodiment of the present invention will be described. In the first embodiment, the frequency of the input clock signal CLKin supplied to the transfer unit 401 within the unit circuit 4 (that is, the frequency of the gate clock signals CLK1, CLK1B, CLK2, and CLK2B) and the frequency of the control clock signals CKX and CKXB supplied to the state memory unit 402 within the unit circuit 4 are the same. On the other hand, according to this embodiment, the frequency of the input clock signal CLKin and the frequency of the control clock signals CKX and CKXB are different. Here, an overall configuration of the liquid crystal display device and a configuration of the gate driver 400 (including a configuration of the shift register 410, a configuration of the unit circuit 4, a configuration of the transfer unit 401, a configuration of the state memory unit 402, and a configuration of the connecting unit 403) are the same as those in the first embodiment (see FIG. 1, FIG. 2, FIG. 3, FIG. 4, FIG. 6, and FIG. 7).

### 2.2 Waveforms of Control Clock Signals

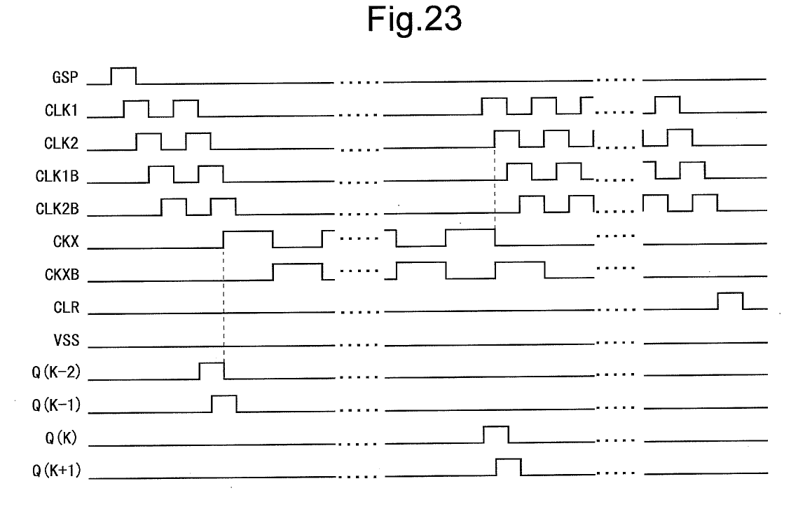

Hereinafter, waveforms of the control clock signals CKX and CKXB according to this embodiment will be described with reference to FIG. 23 to FIG. 28. Here, a K-th stage is taken as the suspension stage. FIG. 23 is a signal waveform diagram for illustration of one example of an operation according to this embodiment. As can be seen from FIG. 23, in this embodiment, the frequency of the control clock signals CKX and CKXB is lower than the frequency of the gate clock signals CLK1, CLK1B, CLK2, and CLK2B. Both of a duty ratio of the control clock signal CKX and a duty ratio of the control clock signal CKXB are one-half.

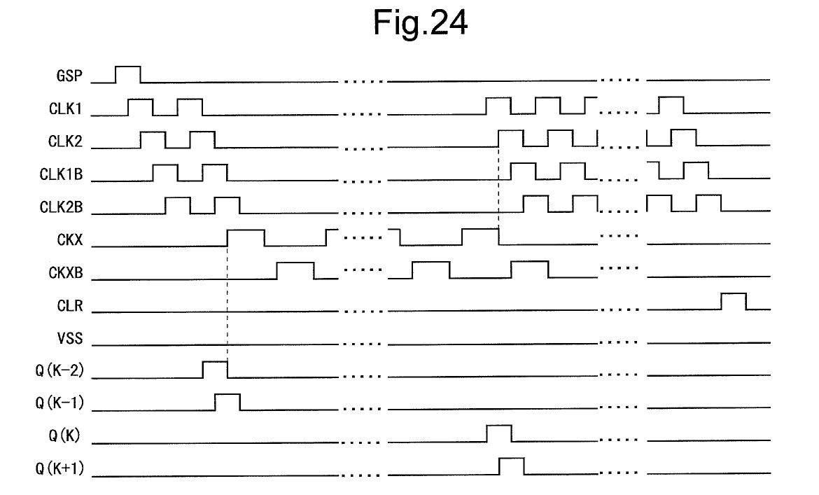

Here, in the example shown in FIG. 23, one of the control clock signal CKX and the control clock signal CKXB is at high level throughout the suspension period. However, as shown in FIG. 24, a period in which both of the control clock signal CKX and the control clock signal CKXB are at low level may be present during the suspension period. Specifically, as long as a period in which both of the control clock signal CKX and the control clock signal CKXB are at high level does not exist, relationship between timing at which the level of the control clock signal CKX changes and timing at which the level of the control clock signal CKXB changes is not particularly limited.

Here, in FIG. 23, a focus is given to timing at which the control clock signal CKX first rises (timing at which the signal changes from low level to high level). Then, as can be seen from FIG. 23, the control clock signal CKX first rises at timing at which the output signal Q(K−2) outputted from the unit circuit 4(K−2) that is 2 stages before the suspension stage falls. The reason why the control clock signal CKX first rises at such timing is as follows.

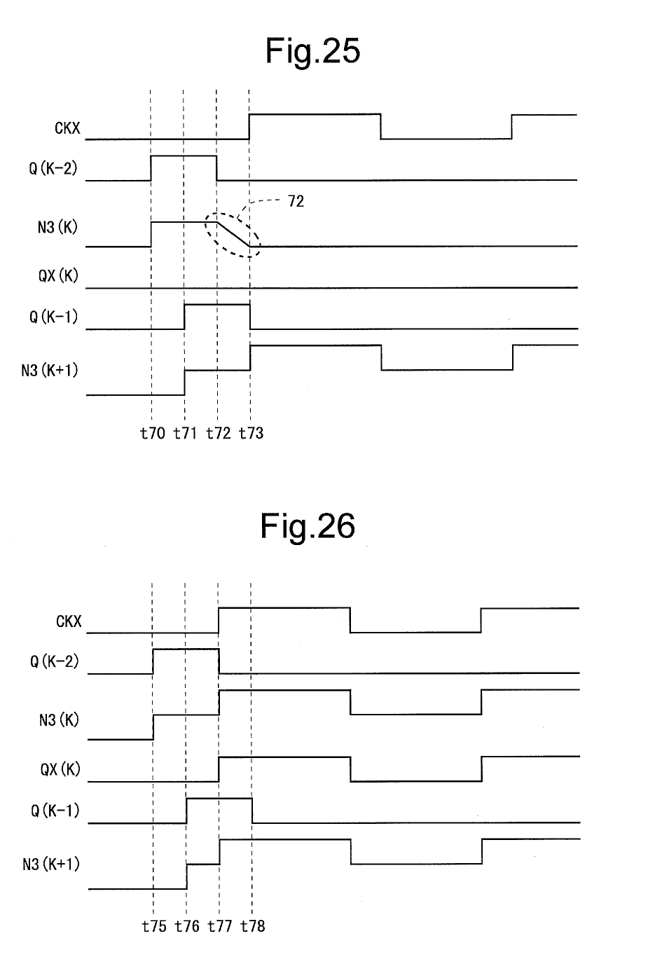

First, it is assumed that the control clock signal CKX first rises at timing delayed from the timing at which the output signal Q(K−2) falls. For example, as shown in FIG. 25, it is assumed that the control clock signal CKX first rises at a time point t73 after the output signal Q(K−2) falls at a time point t72. To the unit circuit 4(K) of the K-th stage, the output signal Q(K−2) outputted from the unit circuit 4(K−2) of a (K−2)th stage is supplied as the set signal S. Therefore, when the output signal Q(K−2) rises at the time point t70, the potential of the third node N3 within the state memory unit 402 of the unit circuit 4(K−2) of the K-th stage changes from low level to high level at the time point t70. Thereafter, when the output signal Q(K−2) falls at the time point t72, supply of an electric charge to the third node N3 within the state memory unit 402 of the unit circuit 4(K−2) of the K-th stage stops. Accordingly, due to charge leakage at the thin film transistors T21, T24, and T25, the potential of the third node N3 gradually decreases after the time point t72 as indicated by a portion denoted by a reference number 72 in FIG. 25. With this, even if the control clock signal CKX rises at the time point t73, the output signal QX(K) does not rise normally in the unit circuit 4(K) of the K-th stage. As a result, in the unit circuit 4(K) of the K-th stage, an electric charge may not be supplied to the first node N1 within the transfer unit 401. Therefore, the scanning is not normally restarted after the suspension period is over. Specifically, an abnormal operation occurs.

By contrast, in a case in which the control clock signal CKX first rises at timing at which the output signal Q(K−2) falls, for example, in a case in which the output signal Q(K−2) falls and the control clock signal CKX first rises at a time point t77 as shown in FIG. 26, an abnormal operation may not occur as describe below. When the output signal Q(K−2) rises at a time point t75, the potential of the third node N3 within the state memory unit 402 of the unit circuit 4(K−2) of the K-th stage changes from low level to high level at the time point t75. Thereafter, when the output signal Q(K−2) falls at the time point t77, supply of an electric charge via the thin film transistor T22 to the third node N3 within the state memory unit 402 of the unit circuit 4(K−2) of the K-th stage stops. However, at the time point t77, as the control clock signal CKX first rises, the potential of the third node N3 increases due to bootstrap. With this, in the unit circuit 4(K) of the K-th stage, the output signal QX(K) normally rises. Thereafter, as the control clock signal CKX rises every predetermined period, even if charge leakage occurs at the thin film transistors T21, T24, and T25, the potential of the third node N3 is maintained at high level. Therefore, the output signal QX(K) rises every predetermined period, and an electric charge is normally supplied to the first node N1 within the transfer unit 401 in the unit circuit 4(K) of the K-th stage. As a result, the scanning is normally restarted after the suspension period is over.

Here, the example in which each of the unit circuits receives the output signal Q outputted from the unit circuit two stages before as the set signal S. However, in the case where each of the unit circuits receives the output signal Q outputted from the unit circuit P stages before (P is an integer no smaller than one) as the set signal S, the level of the control clock signal CKX may be controlled in the following manner. When the clock operation of the gate clock signals CLK1, CLK1B, CLK2, and CLK2B is suspended, the level of the control clock signal CKX is changed from low level (off level) to high level (on level) at timing substantially equal to timing at which the output signal Q outputted from the unit circuit that is P stages before a stage that is to next output the output signal Q at high level (on level) changes from high level (on level) to low level (off level).

Next, in FIG. 23, a focus is given to timing at which the control clock signal CKX last falls (timing at which the control clock signal CKX changes from high level to low level). Then, as can be seen from FIG. 23, the control clock signal CKX last falls at timing at which the gate clock signal CLK2 supplied to the unit circuit 4(K+1) of the (K+1)th stage as the input clock signal CLKin rises. The reason why the control clock signal CKX last falls at such timing is as follows.

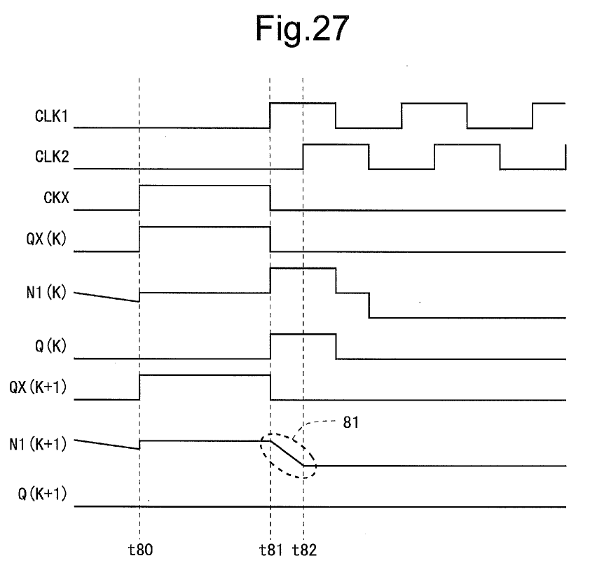

First, it is assumed that the control clock signal CKX last falls at timing earlier than the timing at which the gate clock signal CLK2 rises. For example, as shown in FIG. 27, it is assumed that the control clock signal CKX last falls at a time point t81 which is earlier than a time point t82 at which the gate clock signal CLK2 rises. When the control clock signal CKX rises at a time point t80, an electric charge is supplied to the first node N1 within the transfer unit 401 in the unit circuit 4(K) of the K-th stage by rising of the output signal QX(K), and an electric charge is supplied to the first node N1 within the transfer unit 401 in the unit circuit 4(K+1) of the (K+1)th stage by rising of the output signal QX(K+1). When the control clock signal CKX falls at the time point t81, the output signals QX(K) and QX(K+1) also falls. Further, when the gate clock signal CLK1 rises at the time point t81, since the gate clock signal CLK1 is supplied to the unit circuit 4(K) of the K-th stage as the input clock signal CLKin, the potential of the first node N1 rises due to bootstrap in the unit circuit 4(K) of the K-th stage, and the output signal Q(K) rises. During a period between the time point t81 and the time point t82, the output signal QX(K+1) is at low level, and therefore an electric charge may not be supplied to the first node N1 within the transfer unit 401 in the unit circuit 4(K+1) of the (K+1)th stage. Accordingly, due to charge leakage at the thin film transistors T12, T13, and T16, the potential of the first node N1 gradually decreases during the period between the time point t81 and the time point t82 as indicated by a portion denoted by a reference number 81 in FIG. 27. With this, even if the gate clock signal CLK2 rises at the time point t82, the output signal Q(K+1) does not rise normally in the unit circuit 4(K+1) of the (K+1)th stage. As a result, an abnormal operation occurs.

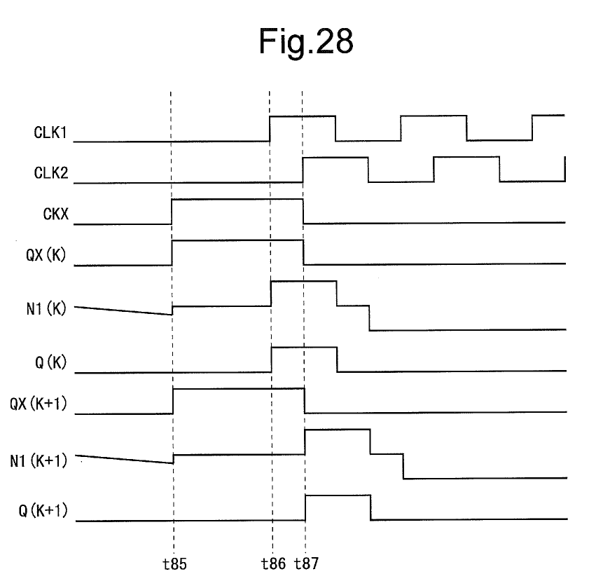

By contrast, in a case in which the control clock signal CKX last falls at timing at which the gate clock signal CLK2 rises, for example, in a case in which the gate clock signal CLK2 rises and the control clock signal CKX last falls at the time point t82 as shown in FIG. 28, an abnormal operation may not occur as describe below. When the control clock signal CKX rises at a time point t85, an electric charge is supplied to the first node N1 within the transfer unit 401 in the unit circuit 4(K) of the K-th stage by rising of the output signal QX(K), and an electric charge is supplied to the first node N1 within the transfer unit 401 in the unit circuit 4(K+1) of the (K+1)th stage by rising of the output signal QX(K+1). When the gate clock signal CLK1 rises at the time point t86, the potential of the first node N1 rises due to bootstrap in the unit circuit 4(K) of the K-th stage, and the output signal Q(K) rises. Here, the control clock signal CKX does not fall at the time point t86. Accordingly, in a period from the time point t86 to the time point t87, the output signal QX(K+1) is maintained at high level. Therefore, in the period from the time point t86 to the time point t87, the potential of the first node N1 is maintained at high level in the unit circuit 4(K+1) of the (K+1)th stage. With this, when the gate clock signal CLK2 rises at the time point t87, the potential of the first node N1 rises due to bootstrap in the unit circuit 4(K+1) of the (K+1)th stage, and the output signal Q(K+1) normally rises.

As described above, when the clock operation of the gate clock signals CLK1, CLK1B, CLK2, and CLK2B is restarted, an occurrence of an abnormal operation is suppressed by controlling the level of the control clock signal CKX in the following manner. The level of the control clock signal CKX is changed from high level (on level) to low level (off level) at timing substantially equal to timing at which, out of the gate clock signals CLK1, CLK1B, CLK2, and CLK2B, a signal (the input clock signal CLKin) supplied to the drain terminal of the thin film transistor T11 included in the transfer unit 401 of the unit circuit 4 of a stage next to a stage that is to next output the output signal Q at on level changes from low level (off level) to high level (on level).

### 2.3 Effects

According to this embodiment, by favorably controlling the timing at which the control clock signal CKX first rises and last falls, it is possible to effectively prevent charge leakage at the thin film transistor within the unit circuit 4. Accordingly, even when a threshold voltage of the thin film transistor within the unit circuit 4 is low, the shift register 410 is able to perform the suspension of scanning at any stage without causing an abnormal operation. In the meantime, in general, power consumption in a circuit is proportional to a product of a capacitance within a circuit, and the square of a voltage (amplitude), and a frequency. In this embodiment, as the frequency of the control clock signals CKX and CKXB is lower than the frequency of the gate clock signals CLK1, CLK1B, CLK2, and CLK2B, power consumption due to an operation of the state memory unit 402 is reduced as compared to the first embodiment. Further, by decreasing on duty of the control clock signals CKX and CKXB as shown in FIG. 24, a length of time during which bias voltages are applied to the thin film transistor T21 within the state memory unit 402 and the thin film transistor T11 within the transfer unit 401 decreases, and therefore it is possible to reduce the threshold shift of the thin film transistors T21 and T11.

### 3. Others

In the embodiments described above, the description is given taking the liquid crystal display device as an example. However, the present invention is not limited to such an example. The present invention may be applied to display devices of other types such as organic electro luminescence (EL).

Further, the configurations of the unit circuit 4, the transfer unit 401, and the state memory unit 402 are not limited to the configurations described above (FIG. 1, FIG. 7, and FIG. 6). For example, the configuration of the state memory unit 402 may be the same as the configuration of the transfer unit 401. Further, for example, a thin film transistor for changing the potential of the second node N2 to low level based on an inversion clock signal of the input clock signal CLKin may be provided within the transfer unit 401, so that the threshold shift of the thin film transistors T16 and T17 within the transfer unit 401 can be reduced. Further, while the four-phase clock signals are used as the gate clock signals in the above embodiments, the present invention is not limited to such an example. Clock signals of phases of a number other than four may be used as the gate clock signal.

Moreover, while the processing for the touch panel is performed during the suspension of the scanning in the above embodiments, the present invention is not limited to such an example. Processing other than the processing for the touch panel may be performed during the suspension of the scanning.

While the present invention has been described in detail in the above, the above description is only exemplary and illustrative, and not restrictive by any means. It is appreciated that a numerous number of variations and modifications may be conceivable without departing the scope of the present invention.

The present application claims priority to Japanese Patent Application No. 2017-196588 filed on Oct. 10, 2017, entitled “Shift Register and Display Device Provided with Same”, which is herein incorporated by reference in its entirety.

What is claimed is:

1. A shift register performing a shift operation based on a shift clock signal group including a plurality of clock signals, the shift register being configured by a plurality of stages, wherein
a unit circuit that forms each of the stages includes:
a transfer unit having a first charge holding node for holding an electric charge in order to output an output signal at on level, the transfer unit being configured to output an output signal at on level based on one of the plurality of clock signals included in the shift clock signal group when a level of the first charge holding node is on level;
a state memory unit having a second charge holding node for holding an electric charge in order to output a charge supply signal at on level, the state memory unit being configured to output a charge supply signal at on level based on a first control clock signal when a level of the second charge holding node is on level; and
a connecting unit that connects the state memory unit with the transfer unit so that an electric charge is supplied to the first charge holding node based on a charge supply signal at on level,
the transfer unit includes:
a first output node configured to output the output signal;
a first output control transistor having: a control terminal connected to the first charge holding node; a first conducting terminal to which one of the plurality of clock signals included in the shift clock signal group is supplied; and a second conducting terminal connected to the first output node;
a first charge-holding node turn-on unit configured to receive an output signal outputted from the unit circuit of a previous stage as a set signal, and to change the level of the first charge holding node to on level based on the set signal; and
a first charge-holding node turn-off unit configured to receive an output signal outputted from the unit circuit of a succeeding stage as a reset signal, and to change the level of the first charge holding node to off level based on the reset signal,
the state memory unit includes:
a second output node configured to output the charge supply signal;
a second output control transistor having: a control terminal connected to the second charge holding node; a first conducting terminal to which the first control clock signal is supplied; and a second conducting terminal connected to the second output node;
a second charge-holding node turn-on unit configured to receive an output signal outputted from the unit circuit of the previous stage as the set signal, and to change the level of the second charge holding node to on level based on the set signal; and
a second charge-holding node turn-off unit configured to receive an output signal outputted from the unit circuit of the succeeding stage as the reset signal, and to change the level of the second charge holding node to off level based on the reset signal, and
clock operation of the first control clock signal is performed when clock operation of the shift clock signal group is suspended.

2. The shift register according to claim 1, wherein
the state memory unit further includes:
a capacitative element having one end connected to the second charge holding node and the other end connected to the second output node;
a second output-node turn-off transistor having: a control terminal to which a second control clock signal whose phase is opposite of a phase of the first control clock signal is supplied; a first conducting terminal connected to the second output node; and a second conducting terminal to which an off-level direct voltage is supplied; and
a second charge-holding node stabilization transistor having: a control terminal to which the first control clock signal is supplied; a first conducting terminal connected to the second charge holding node; and a second conducting terminal connected to the second output node,
the second charge-holding node turn-on unit includes a second charge-holding node turn-on transistor having: a control terminal and a first conducting terminal to each of which a set signal is supplied; and a second conducting terminal connected to the second charge holding node, and
the second charge-holding node turn-off unit includes a second charge-holding node turn-off transistor having: a control terminal to which the reset signal is supplied; a first conducting terminal connected to the second charge holding node; and a second conducting terminal to which an off-level direct voltage is supplied.

3. The shift register according to claim 1, wherein
clock operation of the first control clock signal and clock operation of the plurality of clock signals included in the shift clock signal group are performed separately.

4. The shift register according to claim 1, wherein
a signal supplied to the transfer unit as a set signal and a signal supplied to the state memory unit as a set signal are identical, and
a signal supplied to the transfer unit as a reset signal and a signal supplied to the state memory unit as a reset signal are identical.

5. The shift register according to claim 1, wherein
the connecting unit includes a connecting transistor having: a control terminal and a first conducting terminal that are connected to the second output node; and a second conducting terminal connected to the first charge holding node.

6. The shift register according to claim 1, wherein
the connecting unit includes a connecting transistor having: a control terminal connected to the second output node; a first conducting terminal to which a charge supply control signal for controlling supply of an electric charge to the first charge holding node is supplied; and a second conducting terminal connected to the first charge holding node.

7. The shift register according to claim 1, wherein
a frequency of the first control clock signal is lower than a frequency of the plurality of clock signals included in the shift clock signal group.

8. The shift register according to claim 1, wherein
each unit circuit receives an output signal outputted from the unit circuit P stages before (P is an integer no smaller than one) as a set signal, and
when clock operation of the shift clock signal group is suspended, the first control clock signal changes from off level to on level at timing substantially equal to timing at which the output signal outputted from the unit circuit P stages before a stage that is to next output an output signal at on level changes from on level to off level.

9. The shift register according to claim 1, wherein
when clock operation of the shift clock signal group is restarted, the first control clock signal changes from on level to off level at timing substantially equal to timing at which, out of the plurality of clock signals included in the shift clock signal group, a clock signal supplied to the first conducting terminal of the first output control transistor included in the transfer unit of the unit circuit of a stage next to a stage that is to next output an output signal at on level changes from off level to on level.

10. A display device, comprising:
a display unit on which a plurality of scanning signal lines are arranged; and
a scanning signal line drive circuit configured to drive the plurality of scanning signal lines, wherein
the scanning signal line drive circuit includes the shift register according to claim 1 having the plurality of stages so as to respectively correspond to the plurality of scanning signal lines one by one.
